(19) United States
(12) Patent Application Publication
(10) Pub. No.: US 2025/0318046 A1
(43) Pub. Date: Oct. 9, 2025

(54) PRINTED CIRCUIT BOARD AND METHOD OF MANUFACTURING SAME

(71) Applicant: NITTO DENKO CORPORATION, Osaka (JP)

(72) Inventors: Daisuke YAMAUCHI, Osaka (JP); Yasunari OYABU, Osaka (JP); Rina WATANABE, Osaka (JP)

(73) Assignee: NITTO DENKO CORPORATION, Osaka (JP)

(21) Appl. No.: 18/881,636

(22) PCT Filed: Jun. 29, 2023
(86) PCT No.: PCT/JP2023/024194

§ 371 Date: Jan. 6, 2025

(30) Foreign Application Priority Data
Jul. 7, 2022 (JP) 2022-110013

(51) Int. Cl. H05K 1/02; H05K 3/18

(52) U.S. Cl. CPC H05K 1/0298; H05K 3/18

(57) ABSTRACT

An insulating layer has first and second main surfaces. A conductor layer is on the first main surface. A metallic thin film is on the second main surface, and has a third main surface facing in an opposite direction to the insulating layer. A metallic support is made of a metallic material different from that of the metallic thin film. First and second areas are defined in the first main surface, and the conductor layer forms a wire that extends so as to pass through the first and second areas of the first main surface. In the third main surface, when third and fourth areas that overlap with the first and second areas of the first main surface in a plan view are defined, the metallic support is provided on the third main surface so as not to cover the third area and so as to cover the fourth area.

### TECHNICAL FIELD

The present invention relates to a printed circuit board and a method of manufacturing the printed circuit board.

### BACKGROUND ART

As one example of a printed circuit board, there is a suspension board with a circuit in which an insulating layer is formed on a metallic support substrate, and a conductor layer as a wire is formed on the insulating layer, for example.

### CITATION LIST

### Patent Document

[Patent Document 1] JP 2012-243382 A

### SUMMARY OF INVENTION

### Technical Problem

In recent years, the use of printed circuit boards has been expanding. Depending on the use of a printed circuit board, the printed circuit board may be required to have higher flexibility. In the above-mentioned suspension board with a circuit, a metallic support substrate has relatively high rigidity as compared with an insulating layer and a conductor layer. As such, it is considered that a printed circuit board having high flexibility is realized when a portion of the metallic support substrate is removed from the above-mentioned basic configuration of the suspension board with a circuit.

In the above-mentioned suspension board with a circuit, a portion in which the conductor layer and the metallic supporting substrate face each other with the insulating layer interposed therebetween, the metallic support substrate reduces the impedance of the conductor layer (wire). Therefore, when a portion of the metallic support substrate is removed, the impedance of the conductor layer cannot be reduced. In this case, because the impedance of the conductor layer (wire) deviates from a desired value, the impedance of the conductor layer and the impedance of an electronic component connected to the conductor layer may not match.

Patent Document 1 describes one example of a suspension flexure substrate (printed circuit board) in which an insulating layer and a wire are laminated in this order on a metallic support substrate that is made of stainless steel and has an opening area. In the following description, in regard to the suspension flexure substrate of Patent Document 1, the direction in which the metallic support substrate, the insulating layer and the wire are laminated is referred to as a substrate laminating direction.

In the suspension flexure substrate, an opening area of the metallic support substrate overlaps with a portion of the wire in the substrate laminating direction. Further, in the suspension flexure substrate, a conductor film having a higher conductivity than that of the metallic support substrate is formed in the opening area of the metallic support substrate in order to reduce the impedance of the wire. The conductor film overlaps with a portion of the wire in the substrate laminating direction.

With this configuration, a plurality of portions of the wire overlap with the metallic support substrate or the conductor film in the substrate laminating direction. This reduces the impedance of the wire. However, in the suspension flexure substrate of Patent Document 1, the metallic support substrate and the conductor film are made of materials having at least different conductivities.

A degree to which the impedance of the plurality of above-mentioned portions of the wire can be reduced varies depending on the conductivity of members (the conductor film and the metallic support substrate in the above-mentioned example) that are opposite to each of the plurality of portions of the wire with the insulating layer interposed therebetween in the substrate laminating direction. Therefore, there is the difference between the degree to which the impedance can be reduced in a portion of the wire overlapping with the conductor film in the substrate laminating direction and the degree to which the impedance can be reduced in another portion of the wire overlapping with the metallic support substrate in the substrate laminating direction. The discontinuity of impedance in the wire degrades the electrical characteristics of the wire.

An object of the present invention is to provide a printed circuit board which has high flexibility and has reduced impedance discontinuity, and a method of manufacturing the printed circuit board.

### Solution to Problem

(1) A printed circuit board according to one aspect of the present invention includes an insulating layer having a first main surface and a second main surface that are facing in opposite directions, a conductor layer provided on the first main surface of the insulating layer, a metallic thin film that is provided on the second main surface of the insulating layer and has a third main surface facing in an opposite direction to the insulating layer, and a metallic support made of a metallic material different from a metallic material of at least a portion of the metallic thin film, wherein a first area and a second area that are different from each other are defined in the first main surface of the insulating layer, at least a portion of the conductor layer forms a wire that extends to pass through the first area and the second area of the first main surface, and in a case in which, in the third main surface of the metallic thin film, a third area and a fourth area respectively overlapping with the first area and the second area of the first main surface as viewed in an intersecting direction that is orthogonal to the first main surface are defined, the metallic support is provided on the third main surface so as not to cover the third area of the third main surface and to cover the fourth area of the third main surface.

In the printed circuit board, a portion of the printed circuit board that overlaps with the first area of the first main surface and the third area of the third main surface as viewed in the intersecting direction is referred to as a first board portion. Further, another portion of the printed circuit board that overlaps with the second area of the first main surface and the fourth area of the third main surface as viewed in the intersecting direction is referred to as a second board portion.

In this case, the first board portion includes a portion of the conductor layer, a portion of the insulating layer and a portion of the metallic thin film, and does not include the metallic support. On the other hand, the second board portion includes another portion of the conductor layer, another portion of the insulating layer, another portion of the metallic thin film and the metallic support.

As described above, the first board portion does not include the metallic support. Thus, the first board portion is ensured to have higher flexibility than that of the second board portion. On the other hand, the second board portion includes the metallic support. Thus, the second board portion is ensured to have certain mechanical strength required for supporting the first board portion at another member or for mounting of another member.

Further, in the above-mentioned printed circuit board, the metallic thin film faces each of a portion of the wire formed in the first area of the first main surface and another portion of the wire formed in the second area of the first main surface with the insulating layer interposed therebetween. Thus, the impedance of the one portion of the conductor layer and the impedance of the other portion of the conductor layer are adjusted by the common metallic thin film. This reduces uneven adjustment of the impedance in the plurality of portions of the conductor layer.

As a result, the printed circuit board having high flexibility and reduced impedance discontinuity is realized.
(2) The first area and the second area may be adjacent to each other in the first main surface. In this case, because the first board portion and the second board portion are successively arranged, the first board portion is appropriately supported by the second board portion.
(3) The metallic thin film may include a first metallic film and a second metallic film that are laminated in the intersecting direction, and a metallic material of at least one of the first metallic film and the second metallic film is different from a metallic material of the metallic support.

In this case, the first metallic film and the second metallic film are used as the metallic thin film. Therefore, by suitably determining the metallic material and the like to be used for the first metallic film and the second metallic film, it is possible to form a more appropriate metallic thin film in order to reduce the impedance of the conductor layer. Alternatively, it is possible to form a more appropriate metallic thin film in order to improve the adhesion of the metallic thin film and the metallic support with respect to the insulating layer.
(4) The metallic thin film may include a plating layer. The degree of reduction in impedance of the conductor layer varies depending on the thickness of the metallic thin film. With the above-mentioned configuration, at least a portion of the metallic thin film includes the plating layer. In a case in which the plating layer is formed, it is possible to relatively easily adjust the thickness of the plating layer to be formed by suitably adjusting the processing conditions for plating such as a processing period of time. Therefore, it is possible to form the metallic thin film having a more appropriate thickness for reducing the impedance of the conductor layer.
(5) A thickness of the metallic thin film may be smaller than a thickness of the metallic support. In this case, the first board portion is ensured to have higher flexibility.
(6) A thickness of the metallic thin film may be not less than 20 nm and not more than 5 μm. In this case, the impedance of the conductor layer formed in the first board portion and the second board portion is more appropriately adjusted.
(7) A method of manufacturing a printed circuit board according to another aspect of the present invention includes the steps of preparing a metallic support, forming a metallic thin film made of a metallic material different from a metallic material of the metallic support, on the metallic support, forming, on the metallic thin film, an insulating layer having a first main surface and a second main surface that face in opposite directions such that the second main surface is in contact with the metallic thin film, forming a conductor layer on the first main surface of the insulating layer, and removing a portion of the metallic support after the step of forming a metallic thin film, wherein a first area and a second area that are different from each other are defined in the first main surface of the insulating layer, the step of forming a conductor layer, using at least a portion of the conductor layer, includes forming a wire that extends to pass through the first area and the second area of the first main surface, the metallic thin film has a third main surface that faces in an opposite direction to the insulating layer and is in contact with the metallic support, and in a case in which, in the third main surface of the metallic thin film, a third area and a fourth area that respectively overlap with the first area and the second area of the first main surface as viewed in an intersecting direction orthogonal to the first main surface are defined, the step of removing a portion of the metallic support includes removing a portion of the metallic support located in the third area of the third main surface such that the metallic support does not cover the third area of the third main surface and covers the fourth area of the third main surface.

In the printed circuit board that is fabricated by the above-mentioned manufacturing method, a portion of the printed circuit board that overlaps with the first area of the first main surface and the third area of the third main surface as viewed in the intersecting direction is referred to as a first board portion. Further, another portion of the printed circuit board that overlaps with the second area of the first main surface and the fourth area of the third main surface as viewed in the intersecting direction is referred to as a second board portion.

In this case, the first board portion includes a portion of the conductor layer, a portion of the insulating layer and a portion of the metallic thin film, and does not include the metallic support. On the other hand, the second board portion includes another portion of the conductor layer, another portion of the insulating layer, another portion of the metallic thin film and the metallic support.

As described above, the first board portion does not include the metallic support. Thus, the first board portion is ensured to have higher flexibility than that of the second board portion. On the other hand, the second board portion includes the metallic support. Thus, the second board portion is ensured to have certain mechanical strength required for supporting the first board portion at another member or for mounting of another member.

Further, in the above-mentioned printed circuit board, the metallic thin film faces each of a portion of the wire formed in the first area of the first main surface and another portion of the wire formed in the second area of the first main surface with the insulating layer interposed therebetween. Thus, the impedance of the one portion of the conductor layer and the impedance of the other portion of the conductor layer are adjusted by the common metallic thin film. This reduces uneven adjustment of the impedance in the plurality of portions of the conductor layer.

As a result, the printed circuit board having high flexibility and reduced impedance discontinuity is realized.
(8) The step of forming a metallic thin film may include forming at least a portion of the metallic thin film by sputtering.

In this case, the metallic thin film can be easily formed. Further, the thickness of a sputtered film formed by sputtering can be made sufficiently small to the extent that the flexibility of the printed circuit board is not impaired. Therefore, the first board portion can obtain higher flexibility.
(9) The step of forming a metallic thin film may include forming at least a portion of the metallic thin film by plating.

In this case, the thickness of the plating layer formed by plating can be adjusted relatively easily. Therefore, it is possible to form the metallic thin film having a more appropriate thickness for reducing the impedance of the conductor layer.

### Advantageous Effects of Invention

With the present invention, the printed circuit board having high flexibility and reduced impedance discontinuity is realized.

### BRIEF DESCRIPTION OF THE DRAWINGS

FIG. 1 is a top view of a printed circuit board according to one embodiment of the present invention.

FIG. 2 is a bottom view of the printed circuit board of FIG. 1.

FIG. 3 is a schematic cross-sectional view of a plurality of portions of the printed circuit board of FIG. 1.

FIG. 4 is a schematic cross-sectional view for explaining one example of a method of manufacturing the printed circuit board of FIG. 1.

FIG. 5 is a schematic cross-sectional view for explaining the one example of the method of manufacturing the printed circuit board of FIG. 1.

FIG. 6 is a schematic cross-sectional view for explaining the one example of the method of manufacturing the printed circuit board of FIG. 1.

FIG. 7 is a schematic cross-sectional view of a plurality of portions of a printed circuit board including a metallic thin film according to a first modified example.

FIG. 8 is a schematic cross-sectional view of a plurality of portions of a printed circuit board including a metallic thin film according to a second modified example.

FIG. 9 is a top view of a printed circuit board 1 according to another embodiment.

FIG. 10 is a schematic cross-sectional view of a plurality of portions of the printed circuit board of FIG. 9.

FIG. 11 is a top view of a printed circuit board 1 according to yet another embodiment.

FIG. 12 is a schematic cross-sectional view of a plurality of portions of the printed circuit board of FIG. 11.

FIG. 13 is a schematic cross-sectional view of a plurality of portions of a printed circuit board 1 according to yet another embodiment.

FIG. 14 is a diagram showing the measurement results of the impedance of a conductor layer of each of printed circuit boards of comparative examples 1 and 2, and inventive examples 1 to 3.

### DESCRIPTION OF EMBODIMENTS

A printed circuit board and a method of manufacturing the printed circuit board according to one embodiment of the present invention will be described below with reference to the drawings.

### 1. Basic Configuration of Printed Circuit Board

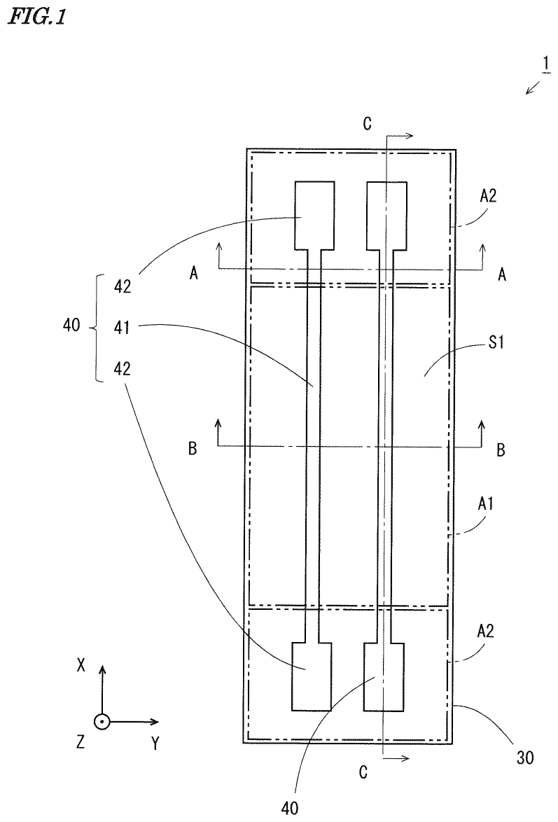

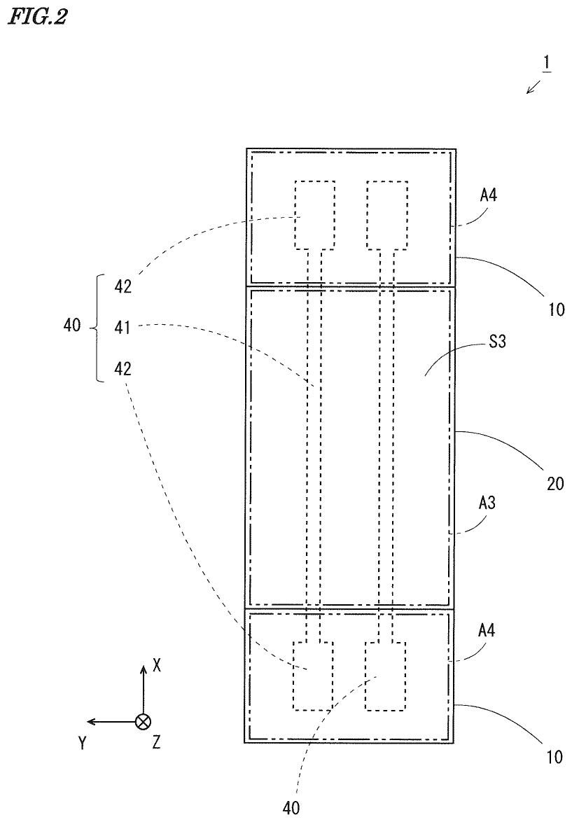

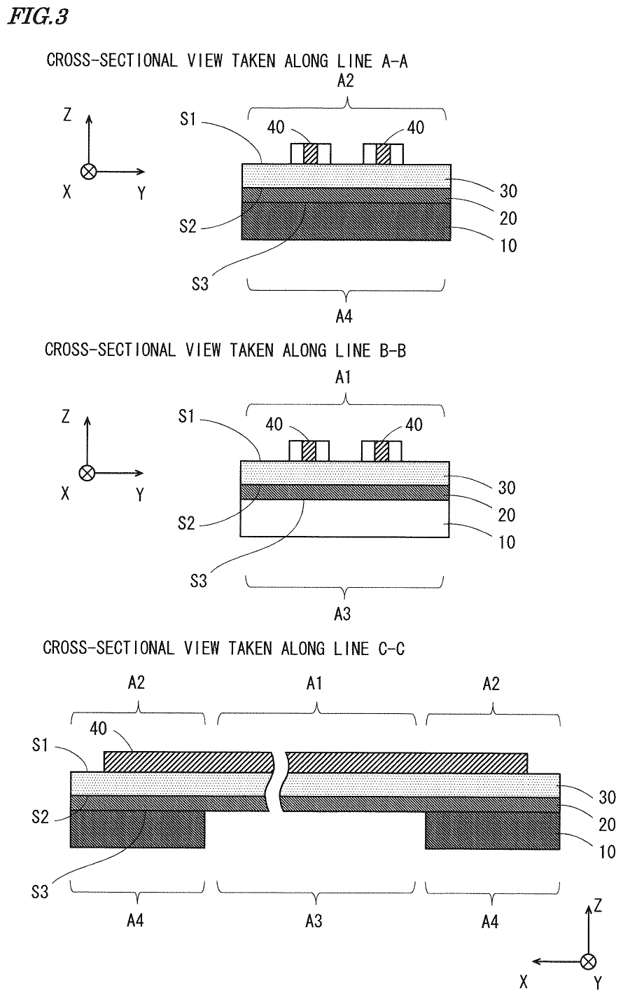

FIG. 1 is a top view of the printed circuit board according to the one embodiment of the present invention. FIG. 2 is a bottom view of the printed circuit board of FIG. 1. FIG. 3 is a schematic cross-sectional view of a plurality of portions of the printed circuit board 1 of FIG. 1. In FIG. 3, the cross-sectional view taken along the line A-A, the cross-sectional view taken along the line B-B and the cross-sectional view taken along the line C-C in FIG. 1 are shown so as to be arranged in this order in the upper field, the center field and the lower field. Here, an X direction, a Y direction and a Z direction orthogonal to one another are defined in order to facilitate understanding of the configuration of the printed circuit board 1. In FIG. 1 and the subsequent drawings, the X direction, the Y direction and the Z direction are suitably indicated by arrows. In the present embodiment, the X direction and the Y direction are orthogonal to each other in a horizontal plane, and the Z direction corresponds to a vertical direction.

As shown in FIGS. 1 and 2, the printed circuit board 1 according to the present embodiment has a rectangular shape extending in one direction (X direction) in a plan view. Further, as shown in FIG. 3, the printed circuit board 1 has a configuration in which a metallic support 10, a metallic thin film 20, an insulating layer 30 and a conductor layer 40 are mainly laminated in this order in the Z direction.

The insulating layer 30 is formed of photosensitive polyimide, for example. The thickness (length in the Z direction) of the insulating layer 30 is not less than 1 μm and not more than 30 μm, for example. The insulating layer 30 may be formed of another synthetic resin such as an acrylic resin, a polyether nitrile resin, a polyether sulfone resin, an epoxy resin, a polyethylene terephthalate resin, a polyethylene naphthalate resin, or a polyvinyl chloride resin.

Further, the insulating layer 30 has two main surfaces (upper surface and lower surface) facing in opposite directions. In the following description, one main surface (upper surface) of the insulating layer 30 is referred to as a first main surface S1, and the other main surface (lower surface) of the insulating layer 30 is referred to as a second main surface S2.

As indicated by the two-dot and dash line in FIG. 1, in the insulating layer 30 of the present example, a first area A1 having a rectangular shape and two second areas A2 having a rectangular shape are set in the first main surface S1. The first area A1 is located in the center portion of the printed circuit board 1 in the longitudinal direction (X direction) of the printed circuit board 1. The two second areas A2 are located at both end portions of the printed circuit board 1 in the longitudinal direction (X direction) of the printed circuit board 1 and in the vicinities thereof. Thus, one of the second areas A2, and the first area A1 are adjacent to each other in the X direction, and the other one of the second areas A2, and the first area A1 are adjacent to each other in the X direction.

Two conductor layers 40 are provided on the first main surface S1 of the insulating layer 30. Each conductor layer 40 is mainly made of copper and is formed on the first main surface S1 of the insulating layer 30 by electrolytic plating. Further, each conductor layer 40 includes a wiring portion 41 and two terminal portions 42. The two terminal portions 42 are respectively arranged in the two second areas A2 at positions in the vicinity of the opposite ends of the printed circuit board 1. Each terminal portion 42 is used for connecting other electronic components or the like to the conductor layer 40 of the printed circuit board 1. The wiring portion 41 continuously extends so as to connect the two terminal portions 42 to each other through one second area A2, the first area A1 and the other second area A2. The thickness (length in the Z direction) of the conductor layer 40 is not less than 0.25 μm and not more than 50 μm, for example. The width (length in the Y direction) of the wiring portion 41 of the conductor layer 40 is not less than 0.25 μm and not more than 50 μm, for example.

The metallic thin film 20 is provided on the second main surface S2 of the insulating layer 30 over the entire second main surface S2. The metallic thin film 20 is formed of metal or an alloy including one or a plurality of types of elements out of copper, chromium, nickel, titanium, iron, molybdenum and tungsten, for example. The metallic thin film 20 of the present example is formed of a single layer made of copper or chromium. The thickness (length in the Z direction) of the metallic thin film 20 is smaller than the thickness (length in the Z direction) of the metallic support 10, described below, and is not less than 20 nm and not more than 5 μm, for example, and is preferably not less than 20 nm and not more than 3 μm.

Similarly to the insulating layer 30, the metallic thin film 20 has two main surfaces (upper surface and lower surface) facing in opposite directions. In the following description, a main surface (lower surface) of the metallic thin film 20 facing in the direction opposite to the insulating layer 30 is referred to as a third main surface S3.

In the third main surface S3 of the metallic thin film 20, a third area A3 and a fourth area A4 respectively corresponding to the first area A1 and the second area A2 of the first main surface S1 of the insulating layer 30 are respectively set. Specifically, the third area A3 of the third main surface S3 is an area overlapping with the first area A1 of the first main surface S1 in a plan view as viewed in the Z direction. Further, the fourth area A4 of the third main surface S3 is an area overlapping with the second area A2 of the first main surface S1 in a plan view as viewed in the Z direction.

On the third main surface S3 of the metallic thin film 20, the metallic support 10 is provided so as not to cover the third area A3 and so as to cover the fourth area A4. The metallic support 10 is made of a metallic material different from that of the metallic thin film 20, and is formed of metal or an alloy including one or a plurality of types of elements selected from the group including copper, chromium, nickel, titanium, iron, molybdenum and aluminum, for example. Here, the metallic material of the metallic support 10 and the metallic material of the metallic thin film 20 being different from each other means that at least one of the electrical conductivity and the relative magnetic permeability of the metallic support 10 is different from one of the electrical conductivity and the relative magnetic permeability of the metallic thin film 20 to the extent that the two metallic materials cannot be regarded as substantially the same. In the present embodiment, the metallic support 10 is formed of stainless steel. The thickness (length in the Z direction) of the metallic support 10 is not less than 10 μm and not more than 250 μm.

### 2. Method of Manufacturing Printed Circuit Board

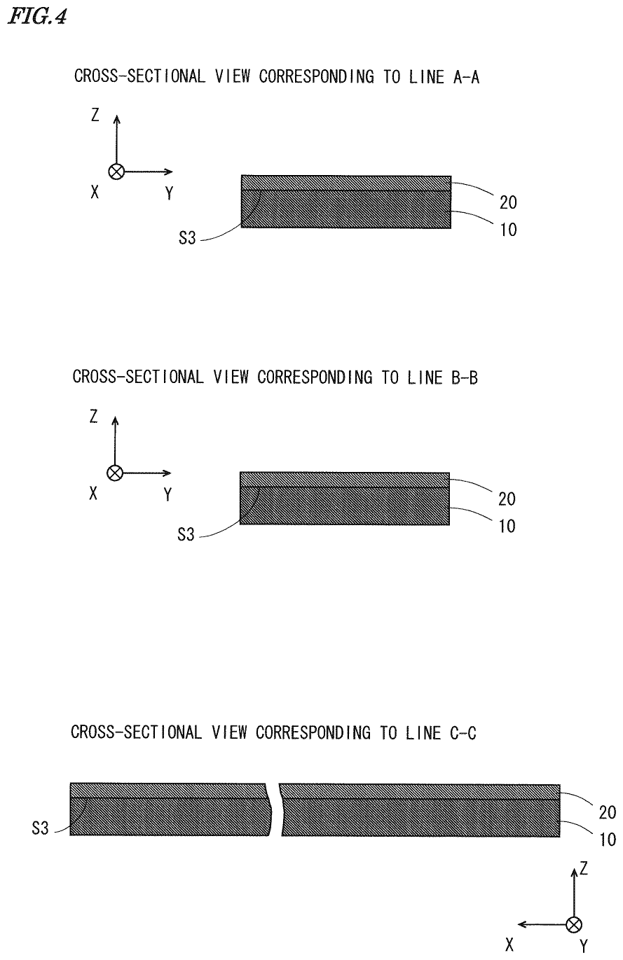

FIGS. 4 to 6 are schematic cross-sectional views for explaining one example of a method of manufacturing the printed circuit board 1 of FIG. 1. In each of FIGS. 4 to 6, similarly to the example of FIG. 3, the three cross-sectional views (corresponding cross-sectional views) corresponding to the line A-A, the line B-B and the line C-C of FIG. 1 are shown so as to be arranged in this order in the upper field, the center field and the lower field.

First, as shown in FIG. 4, the metallic thin film 20 is formed on the upper surface of the metallic support 10. The metallic thin film 20 is formed by a film forming technique such as sputtering, electrolytic plating, electroless plating, chemical vapor deposition or physical vapor deposition. As described above, the metallic thin film 20 of the present example is made of copper or chromium. The lower surface of the metallic thin film 20 that comes into contact with the metallic support 10 is the above-mentioned third main surface S3.

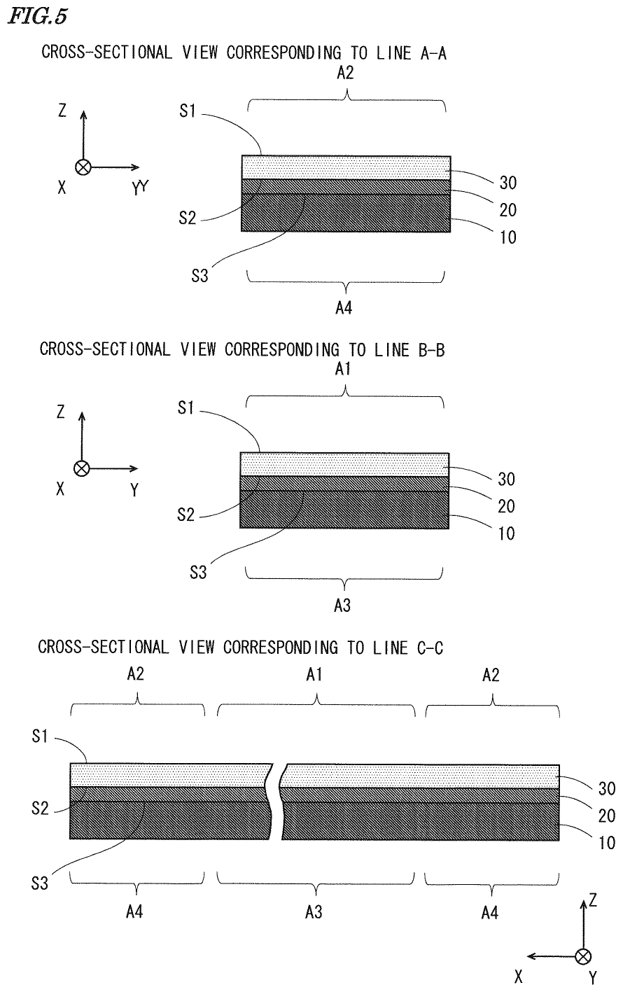

Next, as shown in FIG. 5, the insulating layer 30 made of photosensitive polyimide is formed on the upper surface of the metallic thin film 20. The insulating layer 30 is formed when a precursor of photosensitive polyimide is applied to the entire upper surface of the metallic thin film 20 and the precursor is exposed and developed. Further, the formed insulating layer 30 is subjected to a curing process by heating. The upper surface of the insulating layer 30 exposed upwardly is the above-mentioned first main surface S1, and the lower surface of the insulating layer 30 being in contact with the metallic thin film 20 is the above-mentioned second main surface S2. As described above, the first area A1 and the second area A2 are set in the first main surface S1, and the third area A3 and the fourth area A4 are set in the third main surface S3.

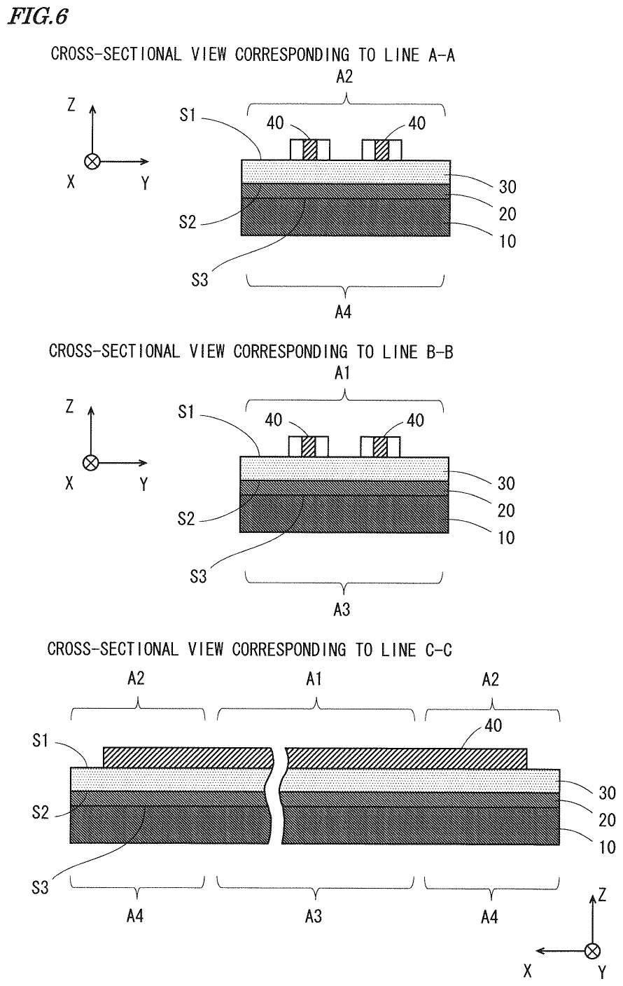

Next, as shown in FIG. 6, one or a plurality (two in the present example) of conductor layers 40 are formed on the first main surface S1 of the insulating layer 30. The conductor layer 40 is formed specifically as follows.

First, a seed layer made of a chromium thin film and a copper thin film, for example, is formed on the first main surface S1 of the insulating layer 30 by sputtering or electroless plating. Next, a plating resist having a predetermined pattern (reverse pattern of the pattern of the two conductor layers 40 of FIG. 1) is formed on the seed layer. Next, on the seed layer exposed through an opening of the plating resist, a plating layer made of copper is formed by electrolytic plating.

Thereafter, the plating resist is stripped and the exposed portion of the seed layer (the portion where the plating layer is not formed) is removed by etching. Thus, the conductor layer 40 formed of the seed layer and the plating layer is formed. In FIGS. 1 and 6 and FIGS. 8, 10, 12 and 13, described below, each of the seed layer and the plating layer that forms the conductor layer 40 is not shown.

A barrier layer for suppressing diffusion of copper may be formed on the exposed outer surface of the conductor layer 40. As the barrier layer, a nickel thin film can be used, for example. The nickel thin film can be formed by sputtering or electroless plating, for example. Further, on the first main surface S1 of the insulating layer 30, a protective film for protecting a plurality of wiring portions 41 may be formed so as to cover the plurality of wiring portions 41 and not to cover a plurality of terminal portions 42. As a material for the protective film, photosensitive polyimide can be used, for example. The protective film made of photosensitive polyimide can be formed by the same method as that for the insulating layer 30.

Finally, a portion of the metallic support 10 located on the third area A3 of the third main surface S3 is removed by wet etching, for example. An etchant to be used then is an etchant capable of dissolving the metallic support 10 at a higher etching rate than the etching rate for the metallic thin film 20. Thus, the third area A3 of the metallic thin film 20 is exposed downwardly, and the printed circuit board 1 of FIGS. 1 to 3 is completed.

The series of above-mentioned processes may be executed by a roll-to-roll method. In this case, a roll (hereinafter referred to as a feeding roll) around which an elongated metallic plate made of stainless steel is wound is prepared, for example. The metallic plate is fed from the prepared feeding roll. The metallic plate fed from the feeding roll is wound around another roll. By execution of the series of above-mentioned processes on each portion of the metallic plate moving from the feeding roll to the other roll, a large number of printed circuit boards 1 can be efficiently manufactured.

### 3. Effects

(1) In the above-mentioned printed circuit board 1, in a plan view as viewed in the Z direction, a portion of the printed circuit board 1 overlapping with the first area A1 of the first main surface S1 and the third area A3 of the third main surface S3 is referred to as a first board portion. Further, in the above-mentioned printed circuit board 1, in a plan view as viewed in the Z direction, another portion of the printed circuit board 2 overlapping with the second area A2 of the first main surface S1 and the fourth area A4 of the third main surface S3 is referred to as a second board portion.

In this case, the first board portion includes a portion of the conductor layer 40, a portion of the insulating layer 30 and a portion of the metallic thin film 20, and does not include the metallic support 10. On the other hand, the second board portion includes another portion of the conductor layer 40, another portion of the insulating layer 30, another portion of the metallic thin film 20 and the metallic support 10.

Thus, the first board portion does not include the metallic support 10. Thus, the first board portion is ensured to have higher flexibility than that of the second board portion. On the other hand, the second board portion includes the metallic support 10. Thus, the second board portion is ensured to have certain mechanical strength required for supporting the first board portion at another member or for mounting of another member.

Further, in the above-mentioned printed circuit board 1, the metallic thin film 20 faces each of a portion of the wiring portion 41 formed in the first area A1 of the first main surface S1 and another portion of the wiring portion 41 formed in the second area A2 of the first main surface S1 with the insulating layer 30 interposed therebetween. Thus, the impedance of the portion of the wiring portion 41 and the impedance of the other portion of the wiring portion 41 are adjusted by the common metallic thin film 20. This reduces uneven adjustment of the impedance in a plurality of portions of the wiring portion 41.

As a result, the printed circuit board 1 having high flexibility and reduced impedance discontinuity is realized.
(2) In the first main surface S1 of the insulating layer 30, the first area A1 is adjacent to each of the two second areas A2. Thus, because the first board portion and the second board portion are successively arranged in the longitudinal direction (X direction) of the printed circuit board 1, the first board portion is appropriately supported by the second board portion.
(3) The thickness of the metallic thin film 20 is smaller than that of the metallic support 10, and is not less than 20 nm and not more than 5 μm. In this case, the first board portion is ensured to have higher flexibility. Further, the impedance of the wiring portions 41 of the conductor layer 40 formed in the first board portion and the second board portion is more appropriately adjusted.

### 4. Modified Examples of Metallic Thin Film 20

### (1) First Modified Example

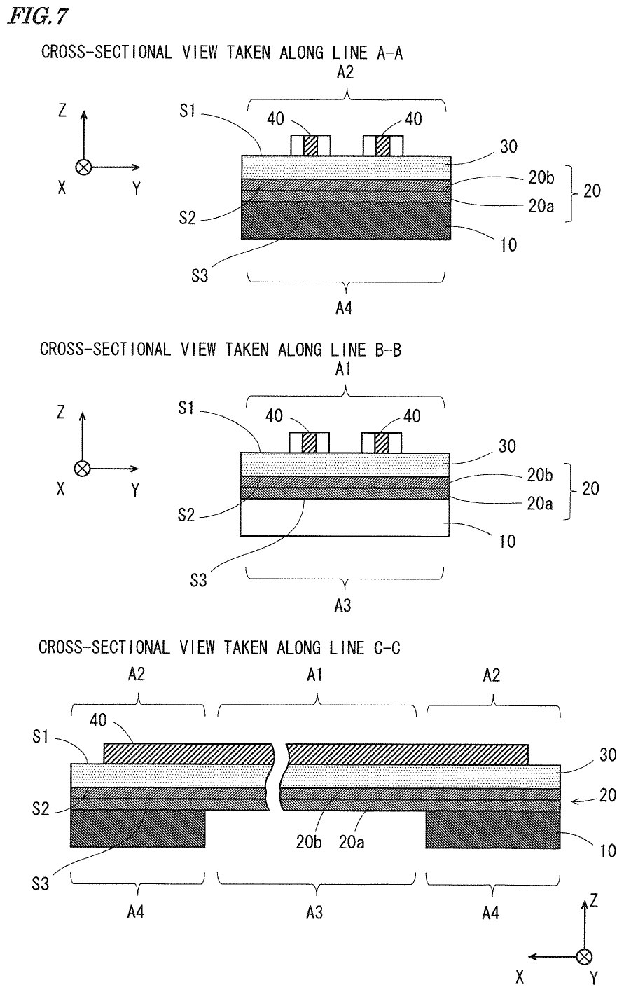

The metallic thin film 20 provided on the printed circuit board 1 may be formed of a plurality of layers. FIG. 7 is a schematic cross-sectional view of a plurality of portions of a printed circuit board 1 including a metallic thin film 20 according to a first modified example. In FIG. 7, similarly to the example of FIG. 3, the three cross-sectional views respectively corresponding to the line A-A, the line B-B and the line C-C of FIG. 1 are shown so as to be arranged in this order in the upper field, the center field and the lower field.

As shown in FIG. 7, the metallic thin film 20 according to the first modified example is formed of a first thin film layer 20a and a second thin film layer 20b. Each of the first thin film layer 20a and the second thin film layer 20b is formed by a film forming technique such as sputtering, electrolytic plating, electroless plating, chemical vapor deposition or physical vapor deposition.

The first thin film layer 20a and the second thin film layer 20b may respectively be a chromium thin film and a copper thin film formed on the upper surface of a metallic support 10 by sputtering. Alternatively, the first thin film layer 20a and the second thin film layer 20b may respectively be a copper thin film and a chromium thin film formed on the upper surface of the metallic support 10 by sputtering.

Alternatively, one of the first thin film layer 20a and the second thin film layer 20b may be formed by electrolytic plating. For example, when the printed circuit board 1 is fabricated, in the above-mentioned step shown in FIG. 4, the first thin film layer 20a made of copper may be formed by electrolytic plating on the upper surface of the metallic support 10. Further, the second thin film layer 20b made of a chromium thin film may be formed on the first thin film layer 20a so as to cover the first thin film layer 20a.

As described below, a degree of reduction of the impedance of the wiring portion 41 varies depending on the thickness of the metallic thin film 20. In electrolytic plating, it is possible to relatively easily adjust the thickness of a plating layer to be formed by suitably adjusting processing conditions such as a processing period of time. Therefore, as described above, in a case in which one of the first thin film layer 20a and the second thin film layer 20b is formed by electrolytic plating, it is possible to form the metallic thin film 20 having a more appropriate thickness for reduction of the impedance of the wiring portion 41.

Further, as described above, in a case in which the upper surface of the metallic thin film 20 is formed of the second thin film layer 20b made of a chromium thin film, because an insulating layer 30 is further formed on the second thin film layer 20b, the adhesion between the first thin film layer 20a and the insulating layer 30 is improved. In a case in which the first thin film layer 20a is formed of a copper thin film, the second thin film layer 20b may be any one of a nickel thin film, a titanium thin film, a molybdenum thin film and a tungsten thin film formed by sputtering, instead of a chromium thin film. Also in this case, the adhesion between the first thin film layer 20a and the insulating layer 30 is improved.

### (2) Second Modified Example

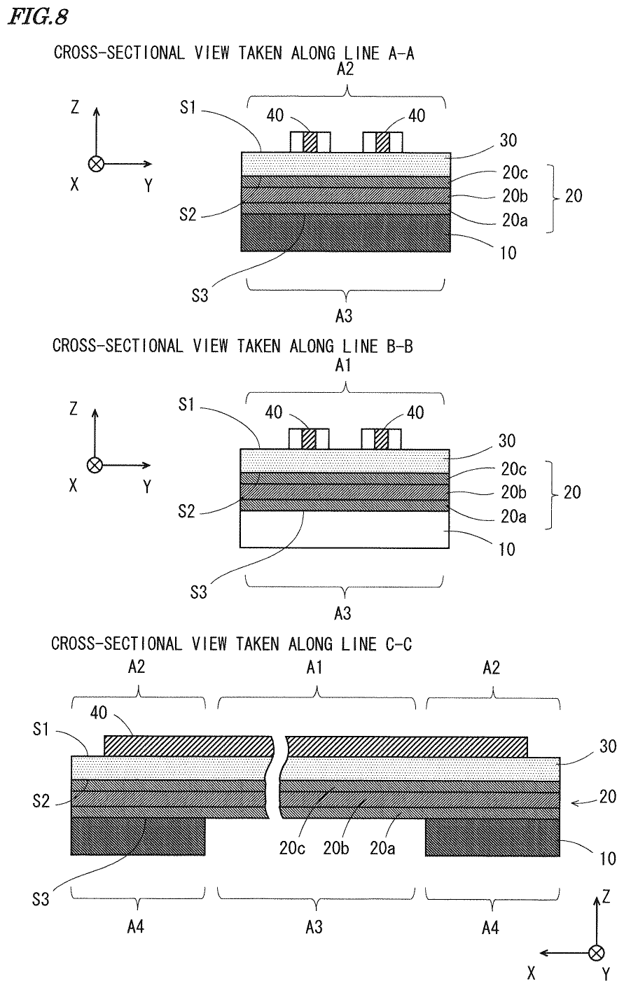

FIG. 8 is a schematic cross-sectional view of a plurality of portions of a printed circuit board 1 including a metallic thin film 20 according to a second modified example. In FIG. 8, similarly to the example of FIG. 3, the three cross-sectional views corresponding to the line A-A, the line B-B and the line C-C of FIG. 1 are shown so as to be arranged in this order in the upper field, the center field and the lower field.

As shown in FIG. 8, the metallic thin film 20 according to the second modified example includes a first thin film layer 20a, a second thin film layer 20b and a third thin film layer 20c. Each of the first thin film layer 20a, the second thin film layer 20b and the third thin film layer 20c is formed by a film forming technique such as sputtering, electrolytic plating, electroless plating, chemical vapor deposition or physical vapor deposition. Each of the first thin film layer 20a, the second thin film layer 20b and the third thin film layer 20c is formed of a metallic thin film such as a copper thin film, a chromium thin film, a nickel thin film, a titanium thin film, a molybdenum thin film or a tungsten thin film.

The first thin film layer 20a and the second thin film layer 20b may respectively be a chromium thin film and a copper thin film formed by sputtering on the upper surface of a metallic support 10. In this case, the third thin film layer 20c may be a copper plating layer formed by electrolytic plating on the copper thin film of the second thin film layer 20b.

Alternatively, the first thin film layer 20a may be a copper plating layer formed by electrolytic plating on the upper surface of the metallic support 10. In this case, the second thin film layer 20b and the third thin film layer 20c may respectively be a copper thin film and a chromium thin film formed by sputtering on the plating layer of the first thin film layer 20a.

Alternatively, the first thin film layer 20a may be a copper thin film formed by sputtering on the upper surface of the metallic support 10. In this case, the second thin film layer 20b may be a copper plating layer formed by electrolytic plating on the upper surface of the metallic support 10. Further, the third thin film layer 20c may be a chromium thin film formed by sputtering on the plating layer of the second thin film layer 20b.

### 5. Other Embodiments

(1) In the first main surface S1 of the insulating layer 30 according to the above-mentioned embodiment, one second area A2 of the two second areas A2, the first area A1, and the other second area A2 of the two second areas A2 are set to be arranged in this order in the X direction. However, the present invention is not limited to the above-mentioned example. In the first main surface S1 of the insulating layer 30, the first area A1 and the second areas A2 may be set as follows.

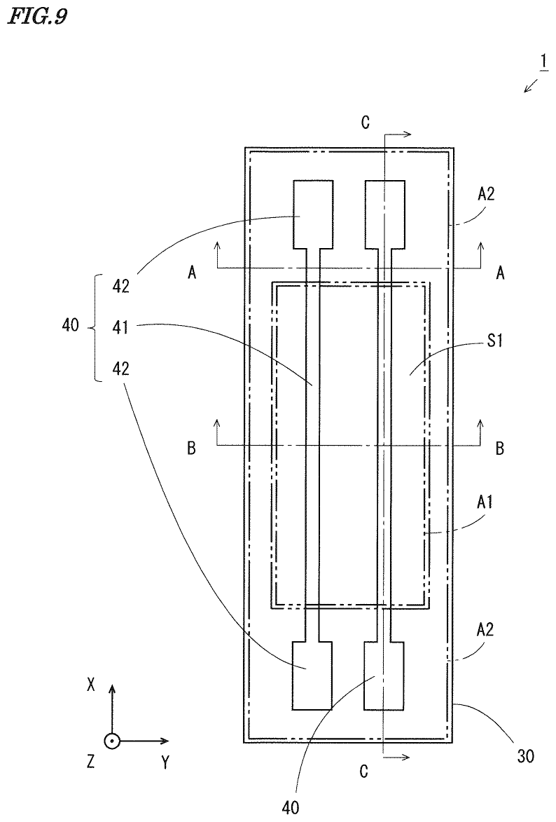

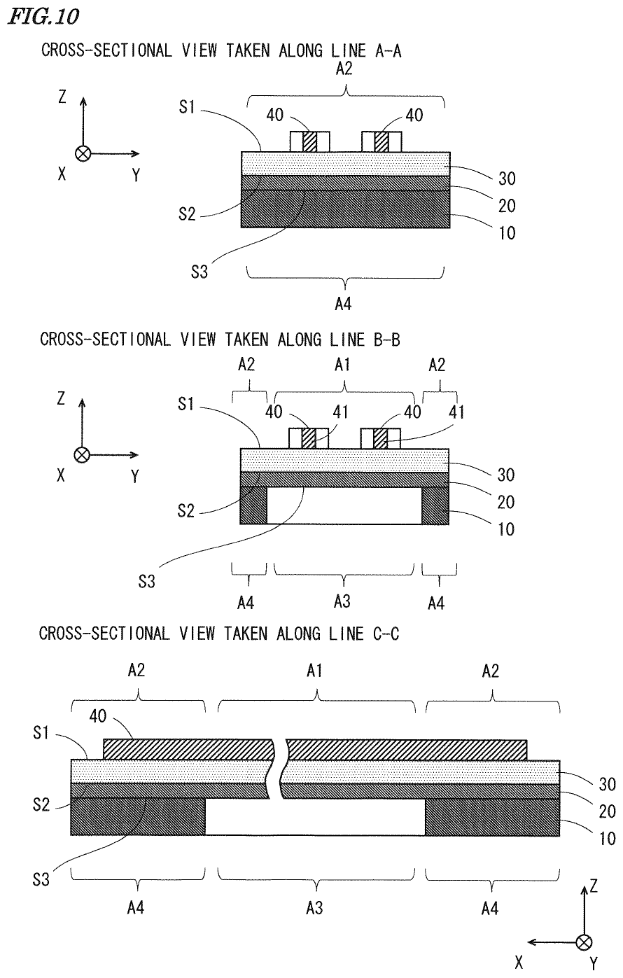

FIG. 9 is a top view of a printed circuit board 1 according to another embodiment. FIG. 10 is a schematic cross-sectional view of a plurality of portions of the printed circuit board 1 of FIG. 9. In FIG. 10, the cross-sectional view taken along the line A-A, the cross-sectional view taken along the line B-B and the cross-sectional views taken along the line C-C in FIG. 9 are shown so as to be arranged in this order in the upper field, the center field and the lower field. Differences of the printed circuit board 1 of FIGS. 9 and 10 from the printed circuit board 1 of FIG. 1 will be described.

In the printed circuit board 1 of FIG. 9, one first area A1 and one second area A2 are set in a first main surface S1 of an insulating layer 30. The first area A1 is set in an island shape at the center portion in the longitudinal direction (X direction) and the transverse direction (Y direction) of the printed circuit board 1. On the other hand, the second area A2 is set so as to surround the first area A1. Similarly to the printed circuit board 1 of FIG. 1, a large portion of wiring portions 41 of two conductor layers 40 are located on the first area A1. The remaining portions of the wiring portions 41 of the two conductor layers 40 and terminal portions 42 of the two conductor layers 40 are located on the second area A2.

As described above, the first area A1 and the second area A2 are set in a first main surface S1. Thus, in the printed circuit board 1 of the present example, in a third main surface S3 of a metallic thin film 20, a third area A3 (not shown) overlapping with the first area A1 of the first main surface S1 is set in a plan view as viewed in the Z direction. Further, in a plan view as viewed in the Z direction, a fourth area A4 (not shown) overlapping with the second area A2 of the first main surface S1 is set.

Thus, as shown in FIG. 10, in the printed circuit board 1 of the present example, at least a portion of a metallic support 10 is located on the third main surface S3 of the metallic thin film 20 over the entire printed circuit board 1 in the X direction. Specifically, in the printed circuit board 1 of the present example, as shown in the center field of FIG. 10, the linear metallic support 10 is provided so as to extend in parallel to the wiring portion 41 at the position in the vicinity of the wiring portion 41 of each conductor layer 40. Thus, necessary mechanical strength can be obtained in the area in the vicinity of the wiring portions 41.

In this manner, it is possible to provide desired flexibility and desired mechanical strength to each of a plurality of portions of the printed circuit board 1 by suitably providing the metallic support 10 in each of a plurality of portions of the printed circuit board 1.
(2) While the printed circuit board 1 according to the above-mentioned embodiment has a rectangular shape extending in the one direction (X direction) in a plan view, the present invention is not limited to this. The printed circuit board 1 may have the following shape.

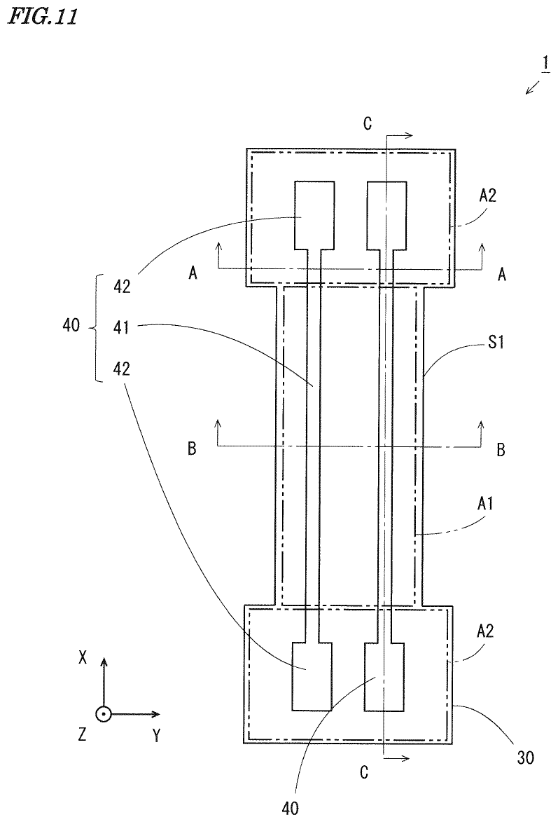

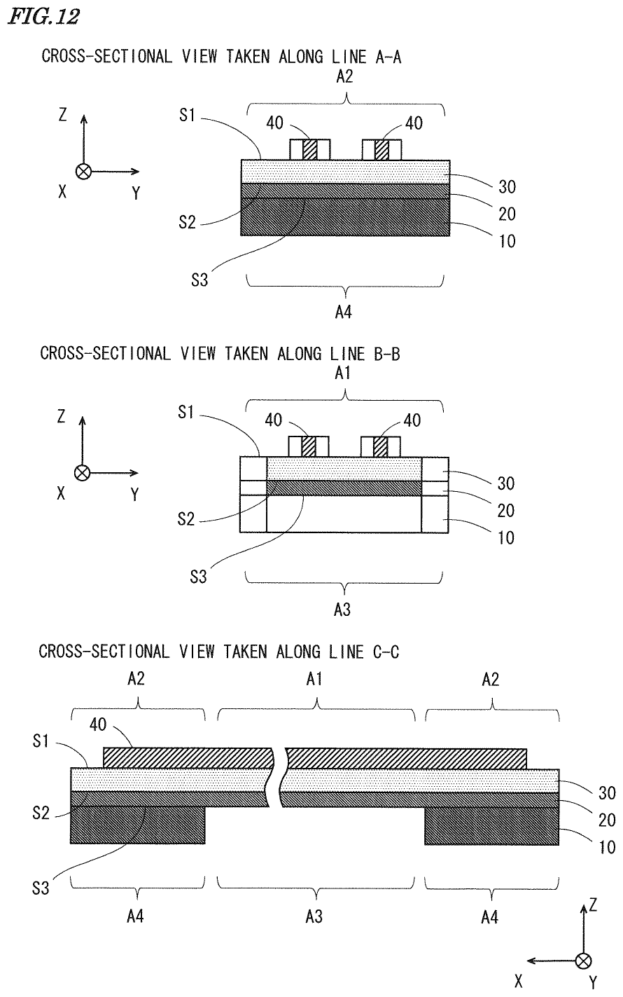

FIG. 11 is a top view of a printed circuit board 1 according to yet another embodiment. FIG. 12 is a schematic cross-sectional view of a plurality of portions of the printed circuit board 1 of FIG. 11. In FIG. 12, the cross-sectional view taken along the line A-A, the cross-sectional view taken along the line B-B and the cross-sectional views taken along the line C-C in FIG. 9 are shown so as to be arranged in this order in the upper field, the center field and the lower field. Differences of the printed circuit board 1 of FIGS. 11 and 12 from the printed circuit board 1 of FIG. 1 will be described.

As shown in FIGS. 11 and 12, the printed circuit board 1 of the present example is formed such that the width (length in the Y direction) of an insulating layer 30 changes in the direction in which wiring portions 41 of two conductor layers 40 extend. Specifically, the insulating layer 30 is formed such that the portions of the insulating layer 30 corresponding to the both end portions in the longitudinal direction (X direction) of the printed circuit board 1 and its vicinities are large, and is formed such that remaining portions of the insulating layer 30 are small. Thus, the width (length in the Y direction) of a first area A1 set in a first main surface S1 is smaller than the width (length in the Y direction) of a second area A2. With this configuration, the portion of the printed circuit board 1 located between the two second areas A2 can have higher flexibility.
(3) While the metallic thin film 20 is formed on the upper surface of the metallic support 10 in the printed circuit board 1 according to the above-mentioned embodiment, the present invention is not limited to this. A new insulating layer 31 may be formed between the metallic support 10 and the metallic thin film 20.

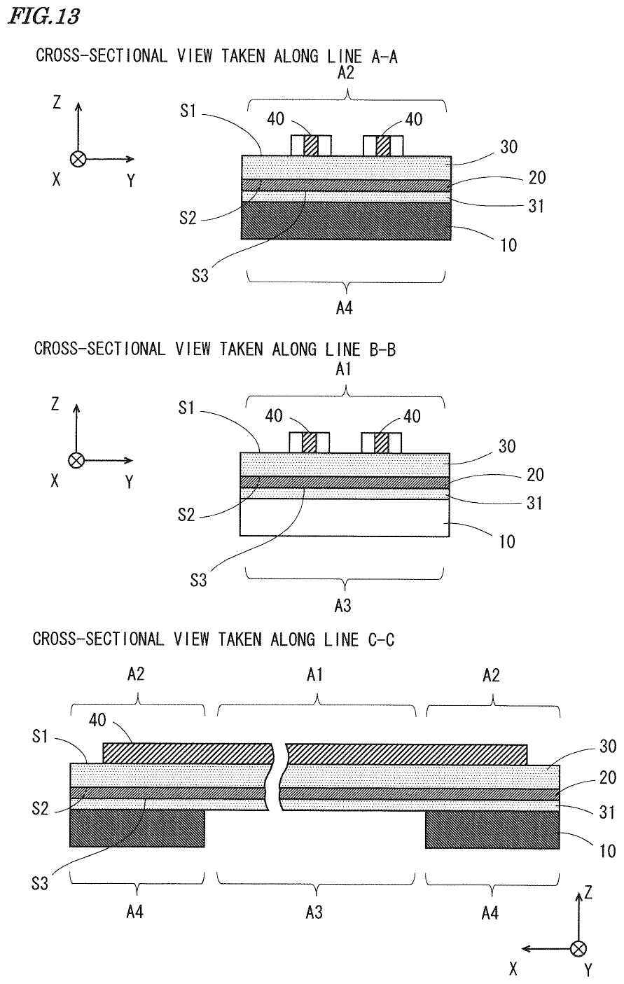

FIG. 13 is a schematic cross-sectional view of a plurality of portions of a printed circuit board 1 according to yet another embodiment. The top view of the printed circuit board 1 of the present example is the same as the top view of the printed circuit board 1 of FIG. 1. In each of FIG. 13, similarly to the example of FIG. 3, the three cross-sectional views respectively corresponding to the line A-A, the line B-B and the line C-C of FIG. 1 are shown so as to be arranged in this order in the upper field, the center field and the lower field.

In the printed circuit board 1 of FIG. 13, a new insulating layer 31 different from an insulating layer 30 is further formed on the upper surface of a metallic support 10. Also in this case, because a metallic thin film 20 is formed to face an entire conductor layer 40 with the insulating layer 30 interposed therebetween, and the same effect as that of the above-mentioned embodiment can be obtained.
(4) When a printed circuit board 1 is manufactured, an insulating layer 30 may be formed using a photosensitive carrier film. Specifically, the insulating layer 30 may be formed by attachment of an insulating film made of photosensitive polyimide onto the upper surface of a metallic thin film 20.
(5) While the metallic thin film 20 is formed so as to overlap with the entire insulating layer 30 in a plan view in the printed circuit board 1 according to the above-mentioned embodiment, the metallic thin film 20 is only required to overlap with the entire conductor layer 40.

For example, in the first main surface S1 of the printed circuit board 1 according to the above-mentioned embodiment, a first area A1 and a second area A2 may be set so as to be spaced apart from each other in the X direction with another new area interposed therebetween. Here, in a case in which a wiring portion 41 of a conductor layer 40 is located on the other new area, a metallic thin film 20 is formed so as to overlap with the first area A1 and the second area A2 and so as to overlap with the other new area in a plan view as viewed in the Z direction. On the other hand, in a case in which the wiring portion 41 of the conductor layer 40 is not located on the other new area, the metallic thin film 20 may be formed so as to overlap with the first area A1 and the second area A2 and so as not to overlap with the other new area in a plan view as viewed in the Z direction.

### 6. Correspondence Between Each Component of the Claims and Each Part of the Embodiments

In the following paragraphs, non-limiting examples of correspondences between various elements recited in the claims below and those described above with respect to various preferred embodiments of the present disclosure are explained. As each of various elements recited in the claims, various other elements having configurations or functions described in the claims can be also used.

In the above-mentioned embodiment, the printed circuit board 1 is an example of a printed circuit board, the first main surface S1 is an example of a first main surface, the second main surface S2 is an example of a second main surface, the insulating layer 30 is an example of an insulating layer, the conductor layer 40 is an example of a conductor layer, the third main surface S3 is an example of a third main surface, and the metallic thin film 20 is an example of a metallic thin film.

Further, the first area A1 is an example of a first area, the second area A2 is an example of a second area, the wiring portion 41 is an example of a wire, the third area A3 is an example of a third area, the fourth area A4 is an example of a fourth area, the first thin film layer 20a is an example of a first metallic film, and the second thin film layer 20b is an example of a second metallic film.

### 7. Test in Regard to Effect of Reduction in Impedance of Wiring Portion 41 by Metallic Thin Film 20

The inventors of the present invention fabricated printed circuit boards of comparative examples 1 and 2 and inventive examples 1 to 3 in order to confirm a degree of reduction in impedance of a plurality of types of metallic thin films 20 and wiring portions 41 corresponding to the plurality of types of metallic thin films 20.

Specifically, the inventors of the present invention fabricated the printed circuit board having the same configuration as that of the printed circuit board 1 of FIGS. 1 to 3 except that the metallic support 10 and the metallic thin film 20 were not included, as the printed circuit board of the comparative example 1.

Further, the inventors of the present invention fabricated the printed circuit board having the same configuration as that of the printed circuit board 1 of FIGS. 1 to 3 except that the metallic thin film 20 was not included and the metallic support 10 was provided to come into contact with the entire second main surface S2 of the insulating layer 30, as the printed circuit board of the comparative example 2. In the printed circuit board of the comparative example 2, the thickness (length in the Z direction) of the metallic support 10 was 18 μm.

Further, the inventors of the present invention fabricated the printed circuit board having the same configuration as that of the printed circuit board 1 of FIGS. 1 to 3 and having the metallic thin film 20 formed of a single layer made of chromium as the printed circuit board of the inventive example 1. The metallic thin film 20 made of chromium was formed by sputtering. In the printed circuit board of the inventive example 1, the thickness (length in the Z direction) of the metallic thin film 20 was 50 nm.

Further, the inventors of the present invention fabricated the printed circuit board having the same configuration as that of the printed circuit board 1 of FIGS. 1 to 3 and having the metallic thin film 20 formed of a single layer made of copper as the printed circuit board of the inventive example 2. The metallic thin film 20 made of copper was formed by sputtering. In the printed circuit board of the inventive example 2, the thickness (length in the Z direction) of the metallic thin film 20 was 50 nm.

Further, the inventors of the present invention also fabricated the printed circuit board having the same configuration as that of the printed circuit board 1 of FIG. 7 as the printed circuit board of the inventive example 3. The first thin film layer 20a was made of chromium and formed by sputtering. The second thin film layer 20b was made of copper and formed by sputtering. In the printed circuit board of the inventive example 3, the thickness (length in the Z direction) of the first thin film layer 20a was 50 nm, and the thickness (length in the Z direction) of the second thin film layer 20b was 50 nm. Therefore, the thickness (length in the Z direction) of the metallic thin film 20 was 100 nm.

In regard to the dimensions for the two wiring portions 41, the printed circuit boards of the comparative examples 1 and 2 and the inventive examples 1 to 3 have equal dimensions for the length, width, interval, thickness and the like. Further, in regard to the thickness of the insulating layer 30, the printed circuit boards of the comparative examples 1 and 2, and the inventive examples 1 to 3 have equal dimensions.

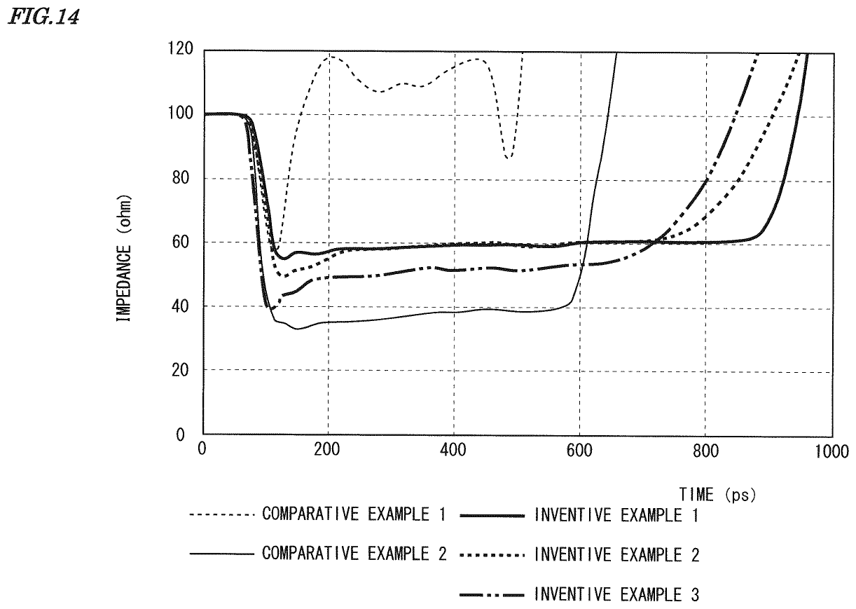

The impedance of the conductor layer 40 was measured by a TDR (Time Domain Reflectometry) method in regard to the plurality of printed circuit boards that were fabricated as described above. FIG. 14 is a diagram showing the measurement results of the impedance of the conductor layer 40 of each of the printed circuit boards of the comparative examples 1 and 2, and the inventive examples 1 to 3.

In FIG. 14, the measurement results of the impedance are shown in a graph. In the graph, the ordinate indicates impedance, and the abscissa indicates time. Further, in the graph of FIG. 14, the measurement result of impedance corresponding to the conductor layer 40 of the comparative example 1 is indicated by the dotted line, and the measurement result of impedance corresponding to the conductor layer 40 of the comparative example 2 is indicated by the solid line. Further, the measurement result of impedance corresponding to the conductor layer 40 of the inventive example 1 is indicated by the thick solid line, the measurement result of impedance corresponding to the conductor layer 40 of the inventive example 2 is indicated by the thick dotted line, and the measurement result of impedance corresponding to the conductor layer 40 of the inventive example 3 is indicated by the thick two-dot and dash line. In the graph of FIG. 14, the impedance shown in the range of about not less than about 200 ps and about not more than 400 ps of the abscissa (time axis) represents the impedance corresponding to the wiring portion 41 of each of the printed circuit boards.

According to the graph of FIG. 14, the impedance of the wiring portion 41 of the comparative example 1 is higher than the impedance of the wiring portion 41 of each of the comparative example 2 and the inventive examples 1 to 3. In contrast, the impedance of the wiring portion 41 of the comparative example 2 is sufficiently lower than the impedance of the wiring portion 41 of each of the comparative example 1 and the inventive examples 1 to 3.

The impedance of the wiring portion 41 of the inventive example 1 and the impedance of the wiring portion 41 of the inventive example 2 are substantially the same, and are sufficiently lower than the impedance of the wiring portion 41 of the comparative example 1, and are slightly higher than the impedance of the wiring portion 41 of the comparative example 2 and the impedance of the wiring portion of the inventive example 3. The impedance of the wiring portion 41 of the inventive example 3 is sufficiently lower than the impedance of the wiring portion 41 of the comparative example 1, and is located between the impedance of the wiring portion 41 of the comparative example 2, and the impedance of the wiring portion 41 of the inventive example 1 and the impedance of the wiring portion 41 of the inventive example 2.

Here, in the printed circuit board of the comparative example 2, in a plan view as viewed in the Z direction, the portion of the metallic support 10 overlapping with each wiring portion 41 functions as an impedance reducing layer for reducing the impedance of the wiring portion 41. On the other hand, in the printed circuit board of each of the inventive examples 1 to 3, the portion of the metallic thin film 20 overlapping with each wiring portion 41 in a plan view functions as an impedance reducing layer for reducing the impedance of the wiring portion 41.

The thickness of the metallic support 10 functioning as the impedance reducing layer in the printed circuit board of the comparative example 2 is larger than the thickness of the metallic thin film 20 functioning as the impedance reducing layer in the printed circuit board of each of the inventive examples 1 to 3. Further, the thickness of the metallic thin film 20 functioning as the impedance reducing layer in the printed circuit board of the comparative example 3 is larger than the thickness of the metallic thin film 20 functioning as the impedance reducing layer in the printed circuit board of each of the inventive examples 1 and 2. In view of these points, it was found that, the larger the thickness of the impedance reducing layer, the larger the degree of reduction in impedance of the wiring portion 41, and the smaller the thickness of the impedance reducing layer, the smaller the degree of reduction in impedance of the wiring portion 41. Therefore, when the printed circuit board 1 according to the present invention is fabricated, the thickness of the metallic thin film 20 overlapping the wiring portion 41 in a plan view is preferably adjusted in accordance with a required degree of reduction in impedance.

1. A printed circuit board comprising:
an insulating layer having a first main surface and a second main surface that are facing in opposite directions;
a conductor layer provided on the first main surface of the insulating layer;
a metallic thin film that is provided on the second main surface of the insulating layer and has a third main surface facing in an opposite direction to the insulating layer; and
a metallic support made of a metallic material different from a metallic material of at least a portion of the metallic thin film, wherein
a first area and a second area that are different from each other are defined in the first main surface of the insulating layer,
at least a portion of the conductor layer forms a wire that extends to pass through the first area and the second area of the first main surface, and
in a case in which, in the third main surface of the metallic thin film, a third area and a fourth area respectively overlapping with the first area and the second area of the first main surface as viewed in an intersecting direction that is orthogonal to the first main surface are defined, the metallic support is provided on the third main surface so as not to cover the third area of the third main surface and to cover the fourth area of the third main surface.

2. The printed circuit board according to claim 1, wherein
the first area and the second area are adjacent to each other in the first main surface.

3. The printed circuit board according to claim 1, wherein
the metallic thin film includes a first metallic film and a second metallic film that are laminated in the intersecting direction, and
a metallic material of at least one of the first metallic film and the second metallic film is different from a metallic material of the metallic support.

4. The printed circuit board according to claim 1, wherein
the metallic thin film includes a plating layer.

5. The printed circuit board according to claim 1, wherein a thickness of the metallic thin film is smaller than a thickness of the metallic support.

6. The printed circuit board according to claim 1, wherein
a thickness of the metallic thin film is not less than 20 nm and not more than 5 μm.

7. A method of manufacturing a printed circuit board, including the steps of:
preparing a metallic support;
forming a metallic thin film made of a metallic material different from a metallic material of the metallic support, on the metallic support;
forming, on the metallic thin film, an insulating layer having a first main surface and a second main surface that face in opposite directions such that the second main surface is in contact with the metallic thin film;
forming a conductor layer on the first main surface of the insulating layer; and
removing a portion of the metallic support after the step of forming a metallic thin film, wherein
a first area and a second area that are different from each other are defined in the first main surface of the insulating layer,
the step of forming a conductor layer, using at least a portion of the conductor layer, includes forming a wire that extends to pass through the first area and the second area of the first main surface,
the metallic thin film has a third main surface that faces in an opposite direction to the insulating layer and is in contact with the metallic support, and
in a case in which, in the third main surface of the metallic thin film, a third area and a fourth area that respectively overlap with the first area and the second area of the first main surface as viewed in an intersecting direction orthogonal to the first main surface are defined, the step of removing a portion of the metallic support includes removing a portion of the metallic support located in the third area of the third main surface such that the metallic support does not cover the third area of the third main surface and covers the fourth area of the third main surface.

8. The method of manufacturing a printed circuit board according to claim 7, wherein
the step of forming a metallic thin film includes forming at least a portion of the metallic thin film by sputtering.

9. The method of manufacturing a printed circuit board according to claim 7, wherein
the step of forming a metallic thin film includes forming at least a portion of the metallic thin film by plating.
